(19) United States
(12) Patent Application Publication
(10) Pub. No.: US 2023/0089612 A1
(43) Pub. Date: Mar. 23, 2023

(54) Method and a system for modular circuit bending and modding of electric and electronic music instruments, audio amplifiers and sound equipment

(71) Applicant: Emil Kindlein, Vienna (AT)

(72) Inventor: Emil Kindlein, Vienna (AT)

(21) Appl. No.: 17/948,679

(22) Filed: Sep. 20, 2022

(30) Foreign Application Priority Data
Sep. 21, 2021 (AT) A 60245/2021

(51) Int. Cl. G10H 1/06; G10H 1/36

(52) U.S. Cl. CPC G10H 1/06; G10H 1/366; G10H 2240/171

(57) ABSTRACT

A method and system for shaping the tone by modular circuit bending and modding of electric and electronic music instruments, audio amplifiers and sound equipment. The design of the system consists of a modding structure of a plurality of inserts, inputs and outputs connections for compatible modules, to reconfigure the electronic circuit without the physical changing of component values and without adding or removing electronic parts of the audio equipment by soldering. A plurality of tone modules for shaping the sound by the intervention into the signal path and a plurality of modules for shaping the tone by other sound design methods that are not part of the signal path are provided. For the modular system, an external device can be used as a multiplier, which consists of a plurality of inserts, inputs and outputs connections for compatible modules also including a plurality of combined series/parallel circuits of freely selectable inputs and outputs for the direct swap of a plurality of modding modules. In addition, switching options are available to control bypass, for advanced series or parallel connections, and for AB testing capabilities. The modular modding system can be used as a standalone device or as an upgrade to existing equipment.

### CROSS-REFERENCE TO RELATED APPLICATIONS

A 60245/2021 issued by the Austrian Patent Office on the 21 Sep. 2021

### STATEMENT REGARDING FEDERALLY SPONSORED RESEARCH OR DEVELOPMENT

“Not Applicable”

### THE NAMES OF THE PARTIES TO A JOINT RESEARCH AGREEMENT

“Not Applicable”

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

“Not Applicable”

### STATEMENT REGARDING PRIOR DISCLOSURES BY THE INVENTOR OR A JOINT INVENTOR

“Not Applicable”

### (g) BACKGROUND OF THE INVENTION

### (1) Field of the Invention

The present invention relates generally to electric and electronic music instruments, audio amplifiers and sound equipment. In particular, the invention relates to modular circuit bending and modding of electric and electronic instruments, audio amplifiers and sound equipment.

### (2) Background Art

From the pickup to the speaker, the electromagnetic pulse of an electric or electronic instrument is shaped by each stage of the signal path. The basics of tone control circuitry are well known in the art and need not to be repeated here. It is enough to say that the tone character and sound is determined by the choice of the built-in electronic components of the instrument maker and audio designer.

The player of an electric instrument today is faced with a vast variety of instruments, amplifiers and musical devices. The wide range of products in the music industry ranges from the most complex devices to the simplest designs. However, the musician is limited either to be satisfied with the specific sound of a particular device or to purchase more models of music gear.

U.S. Pat. No. 6,376,761 discloses a “modular musical instrument amplification system” that allows the musician to add pre-amplification modules in order to achieve different sounds characters. However, this method has a narrow applicability due to the limitation that only the preamplifier modules are interchangeable and that many of the modules recreate the gain and tone profiles of popular traditional amplifiers.

US 2019/0051273 discloses a “modular musical instrument amplification system with adjustable input amplification stage response”. Although this method offers expanded sound possibilities, the choices are limited to the combinations of the existing built-in circuits.

Furthermore, a report at the Gitec Forum describes a “Modular Tube Guitar Amplifier” by Prof. Zollner, which provides a switchable selection for direct comparison between tubes, transformers, circuits and settings. Although this unit is capable of shaping the sound from the instrument input to the speaker, the choice is further limited by the built-in circuitry available. For example only Fender, Vox or Marshall “period-correct” tonestacks can be emulated. In addition, as mentioned at the end of the article, this experimental amplifier is not suitable for either the stage nor the studio due to the overly complicated transport and set-up. https://www.gitec-forum-eng.de/wp-content/uploads/2019/12/modular-tube-amplifier.pdf

Over the years, together with the development of the instrument and audio equipment industry, modding and circuit bending of this musical gear has received considerable attention, with the aim of either achieving “period-correct” historical sounds or developing new innovative tones.

According to the prior art, the bending of circuits would not be possible without technical intervention. Changing component values and adding or removing electronic parts wouldn't have been possible without soldering.

When modding equipment, bending circuits, and generally doing DIY work on the circuit, the results are obviously dependent on the electronic knowledge of the user. Without a professional build structure, such an intervention can very often lead to damaging the audio equipment. Moreover, by patching different audio modules, the lengthening of the signal path can cause sonic losses and interference, even if the wiring is done with high quality wires. According to the prior art the patch cables needed to be routed around the chassis of the musical gear from front to back and back to front regardless how big the piece of equipment was.

### BRIEF SUMMARY OF THE INVENTION

In accordance with the present invention, the limitations of the prior art are overcome by providing a method and system that allows the musician-user to mod and bend circuits in order to shape the tone, without the physical intervention in the electronic circuit of an electric and electronic music instruments, audio amplifier or sound equipment by soldering.

In an advantageous embodiment of the present invention the modular modding system of an electric and electronic music instruments, audio amplifier or sound equipment includes:
a modding structure of a plurality of inserts, inputs and outputs for tone control modules, to reconfigure the electronic circuit without the physical changing of component values and adding or removing electronic parts of the audio equipment,
a plurality of modules that the user is able to swap in order to achieve a great flexibility of tone shaping.

Practically an unlimited selection of tone control modules are provided in the present invention, which are differentiated according to the following characteristics:

1) by type of electronic circuitry—instrument tone controls, gain section tone controls, tonestacks, power amp tone controls, passive or active equalizers, coupling capacitor selector, negative feedback adjustment, other sound design methods that are not connected to the signal path, period-correct, modern circuits or new circuits obtained by modding or circuit bending;
2) by audio connector options—the modules work with any conventional connectors or custom connectors can be produced;
3) by type of power supply—DC input jacks or battery connection option for active equalizers;
4) by the number of units—1, 2, 3 ore more unit modules;
5) according to the form of the module—different optimized geometrical forms and sizes.

Furthermore, in accordance with the present invention, a multitude of insert options in the electronic circuit of the audio equipment are provided by the the modular modding system with insert possibilities after the instrument's pickup, before the preamp, in the preamp block, in the power amp, and at other locations that are not part of the signal path.

In addition, the variety of insertion options is expanded by the advantageous embodiment of the multiplier. To connect the tone control modules no installation is required. The modules can be swapped without turning the audio equipment on and off.

In addition to the great flexibility of the modular modding system comprising the modding structure, the multiplier and a large number of tone control modules, the system according to the present invention offers:
meaningful AB test possibilities,
series, parallel or combined connection possibilities of the tone modules,
bypass functions of the modules.

It is obvious that lengthening the signal path can cause sonic losses and interference, even if the wiring is done with high quality wires. According to the present invention, the audio equipments are provided with at least one front to rear orifice in the chassis which serves as a cable-tray to shield and shorten the signal path. The shape and size of the cross-section of the orifice-cable-tray is optimized as required and metal and/or ferrite core shields are used for interference suppression.

The term “modding” as used in the specification and claims refers to:
modifying devices to perform a function not originally conceived or intended by the instrument maker and audio designer,
the bending of circuits (circuit bending), as an experimental modification of devices,
the DIY (Do-It-Yourself) activity,
the customization of devices to achieve a bespoke specification,
the installation of new technologies.

### BRIEF DESCRIPTION OF THE SEVERAL VIEWS OF THE DRAWING(S)

The figures are to be understood as illustrative and are not intended in any way to limit the scope of the invention.

FIG. 1A, FIG. 1B and FIG. 1C are each a front view of a first embodiment of a modular modding system exemplified on three electric instruments, showing the plug-in possibilities of different tone control modules in accordance with the present illustrated invention.

FIG. 2A and FIG. 2B is a front view of a second embodiment of a modular modding system exemplified on an audio amplifier, showing a number of plug-in possibilities of tone control modules, at different points in the signal path, in accordance with the present invention.

FIG. 3A and FIG. 3B are each a perspective view of an embodiment of a multiplier, illustrating respectively a passive and active variant, in accordance with the present invention.

FIG. 4A, FIG. 4B and FIG. 4C show a schematic diagram of the first embodiment, respectively FIG. 1A, FIG. 1B and FIG. 1C.

FIG. 5 shows a schematic diagram of the second embodiment FIG. 2.

FIG. 6A and FIG. 6B shows a schematic diagram of the third embodiment respectively FIG. 3A and FIG. 3B.

FIG. 7A and FIG. 7B is a front view of an example embodiment of a modular modding system with bypass and AB switch respectively bypass and series/parallel switch.

FIG. 8 is a front view of an example embodiment of a modular modding system of an audio amplifier in combination with a fixed tone control.

### DETAILED DESCRIPTION OF THE INVENTION

It is the object of the present invention to offer the user a variety of modding options to reconfigure the tone controls of an instrument, amplifier or musical device. The parts that make up the present invention are as follows:

1) a plurality of modular modding structures 1, 2, 3, 4, 40, 41, 42;
2) multiple multiplier options 5, 6;
3) and a variety of tone control modules 7, 8, 9, 10, 11, 12, 13, 14, 15, 16, 17.

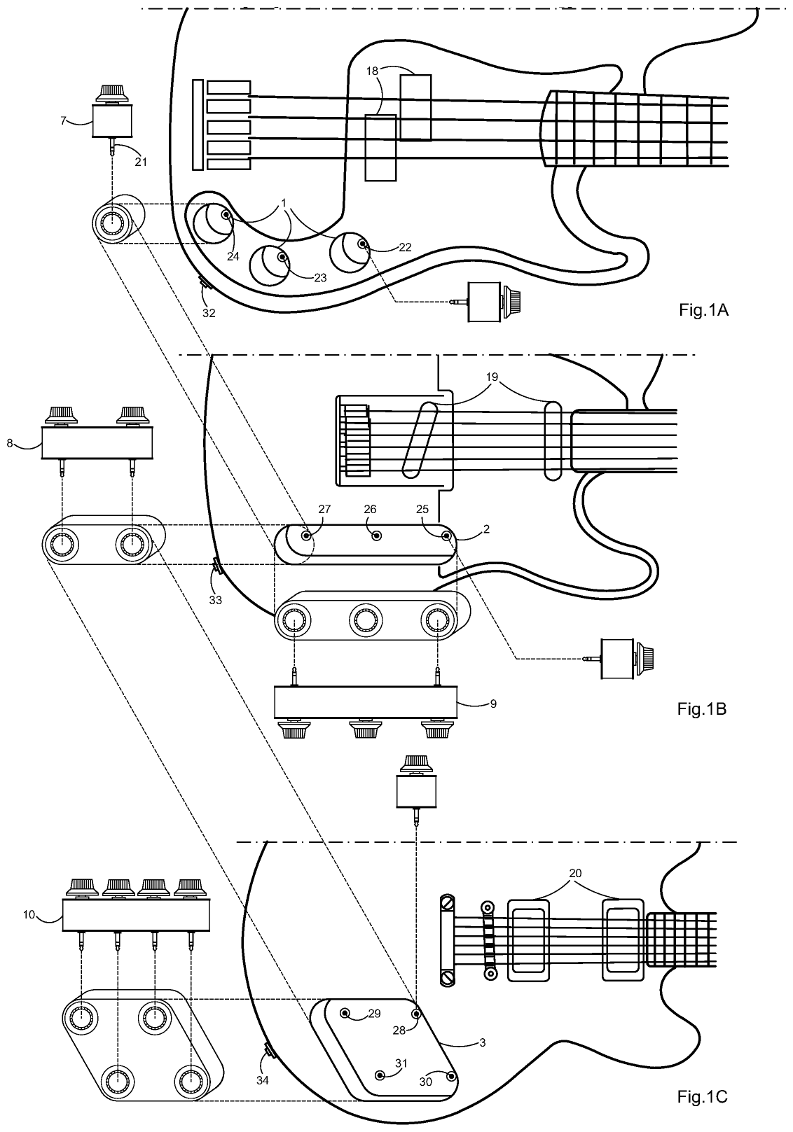

In the first embodiment, modular modding structures 1, 2, 3 are provided right after the pickups 18, 19, 20 of the electric instrument, which are shown in three variations FIG. 1A, FIG. 1B, FIG. 1C. For the various tone control modules 7, 8, 9, 10 matching cavities are milled on the body of the instrument. Jack plugs and sockets 21, 22, 23, 24, 25, 26, 27, 28, 29, 30, 31 are shown for connecting the modules to the modular modding structure, but other standard audio connectors may serve this purpose. The shape of the millings and the distance between the audio sockets 25, 26, 27, 28, 29, 30, 31 allow different combinations of tone control modules 7, 8, 9, 10.

According to the first embodiment, FIG. 4A, FIG. 4B, FIG. 4C show examples of series and parallel connection options in various combinations. The audio signal is passed from the pickups 18, 19, 20 through the sockets 22, 23, 24, 26, 27, 28, 29, 30, 31 and selector switches 25, 35 to the output socket 32, 33, 34. The jacks work as an insert with send-return function. When no tone control module 7, 8, 9, 10 is plugged in via the male stereo plug, the female audio jacks 22, 23, 24, 25, 26, 27, 28, 29, 30, 31 have a “true bypass” function.

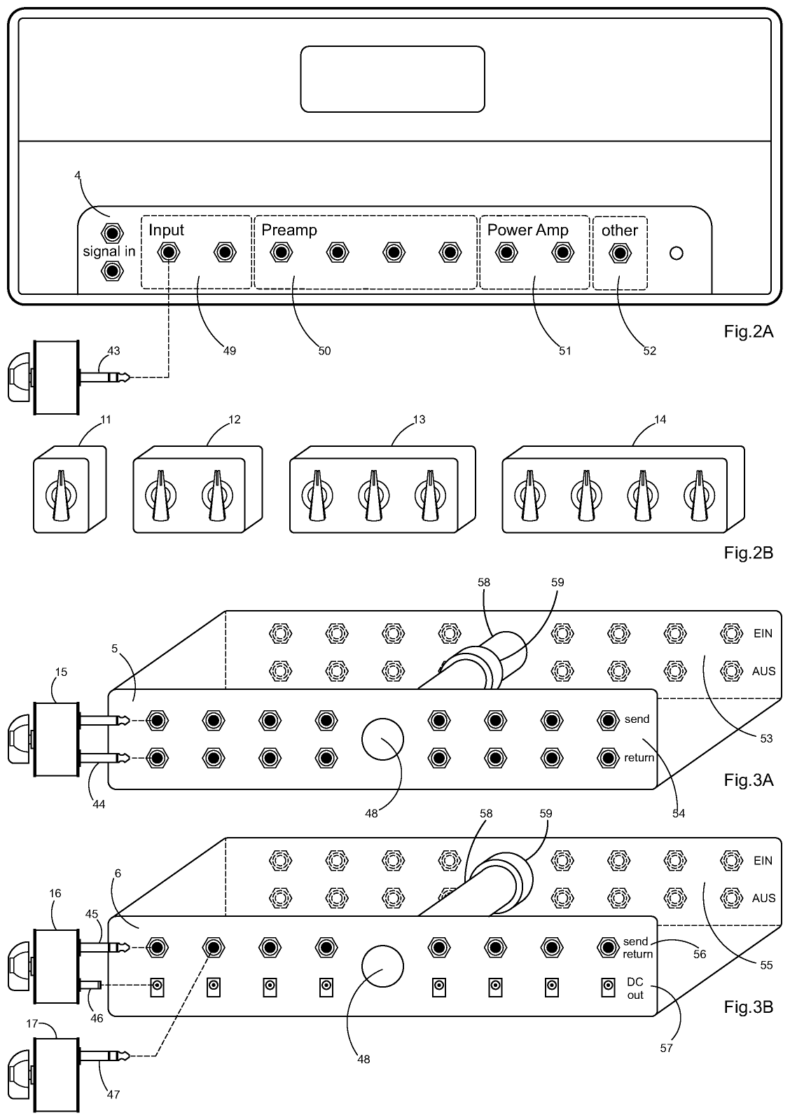

In the second embodiment of FIG. 2A, a modular modding structure 4 is shown with plug-in options at various points in the signal path of an audio amplifier: before the preamplifier 49, in the preamplifier block 50 and in the final stage 51. Another insert option 52 that does not connected to the signal path is marked with “other”. Jack plugs and sockets are shown for connecting tone control modules 11, 12, 13, 14 to the modular modding structure 4, but other standard audio connectors can serve this purpose too.

According to an aspect of the second embodiment, as shown in FIG. 5, the connectors have an insert send-return function. When no tone control module 11, 12, 13, 14 is plugged in via the male stereo connector, the female audio connectors 49, 50, 51, 52 have a “true bypass” function.

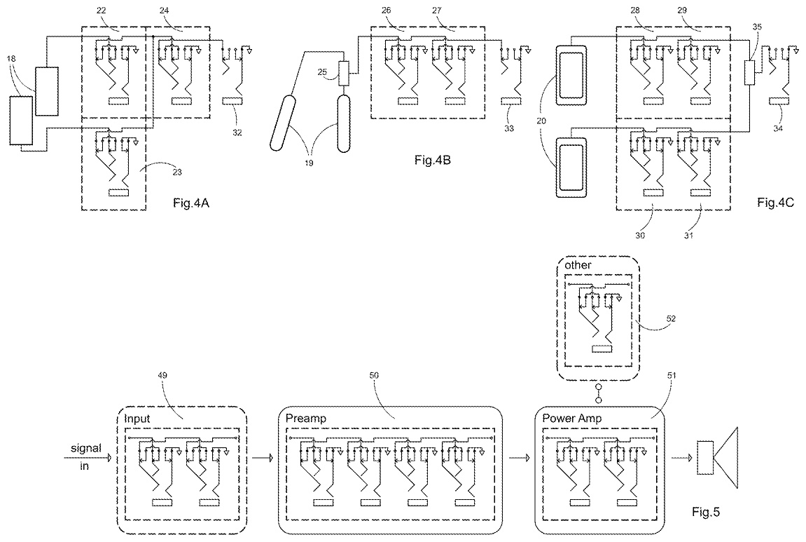

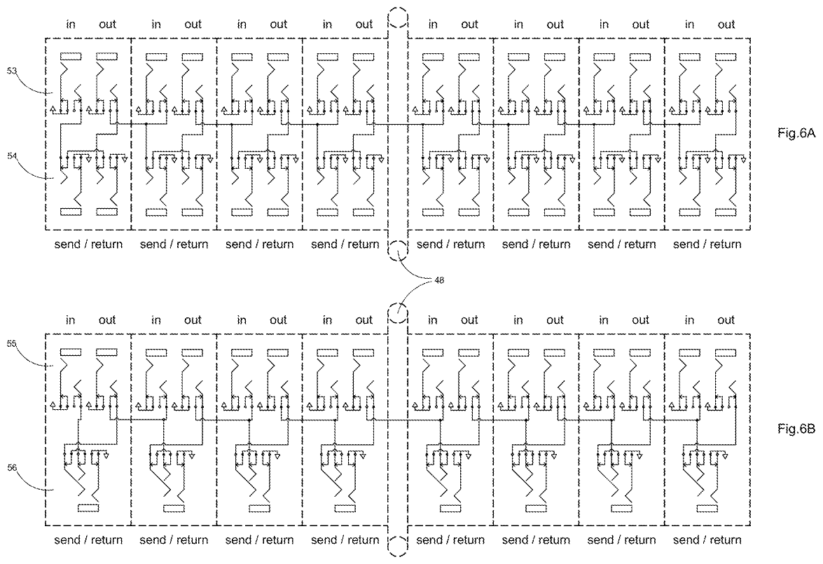

In the third embodiment of FIG. 3A and FIG. 3B, a multiplier 5 and 6 with a variety of plug-in options is illustrated. The multiplier can be connected to the inserts 49, 50, 51, 52 of the modular modding structure 4. A passive FIG. 3A and an active FIG. 3B multiplier are shown that math the appropriate terminals of the tone control modules 15 16, 17. On the front, the multiplier can accommodate different modules 11, 12, 13, 14. The active variant is equipped with DC output sockets 57 which are not shown on the circuit diagram of FIG. 6B. On the rear, both multipliers have a 53 and 55 series of in/out socket pairs.

According to an aspect of the third embodiment as shown in FIG. 6A and FIG. 6B, the mono connection pairs 54 work as an insert send-return path in the passive multiplier. The stereo connections 56 in the active multiplier have the same send-return function. Both multipliers have mono in/out socket pairs 53, 55 provided on the rear side, whereby they can be connected to the 49, 50, 51, 52 connections of the audio amplifier FIG. 2A with Y-splitter cables as desired. When plugging in the two mono jacks of the Y-cable, the “in” jack and the “out” jack have a decoupling function from the preceding channel and the next channel. In this way, adjacent channels can be grouped and used as independent blocks. In addition, the tone control modules can be connected to the front side 54 of the multiplier with patch cables that can be plugged into one another (stack cable) in various series and/or parallel circuit combinations.

According to the third embodiment, in FIG. 3A, FIG. 3B, FIG. 6A and FIG. 6B an front to rear orifice cable tray 48 in the chassis of the multiplier is exemplified in tube form.

The present invention refers to an advantageous embodiment of sound and audio equipment that is provided with at least one front to rear orifice in the chassis that serves as a cable-tray for the patch cables. The shape and size of the cross section of the orifice-cable-tray can be optimized according to the number of patch cables. The shielding of the orifice-cable-tray can be made of metal and/or ferrite. An exemplary embodiment is shown in FIG. 3A and FIG. 3B made of metal tube 58 and ferrite core 59, respectively. As shown, the ferrite core 59 can be moved to various positions. For increased damping of the occurring electrical and/or magnetic disturbances more ferrite cores can be used.

In the fourth embodiment, tone control modules 7, 8, 9, 10, 11, 12, 13, 14 are shown. Their functions and use are illustrated and can be grouped by:

1) position of audio modules in the tone chain: instrument tone controls 7, 8, 9, 10 after the instrument pickup 18, 19, 20; gain section tone controls 49 before preamp; tonestacks 50 in preamp block; power amp tone controls 51 in the power amplifier;
2) modules not connected to the signal path: other circuitry 52 for sound shaping options;
3) according to audio connector options—in the present invention 3.5 mm 21 and 6.35 mm 43, 44, 45, 47, stereo 21, 43, 45, 47 and mono 44 jack plugs are depicted, but other standard audio connectors may also be used be used;
4) passive 17 and active 16 equalizer modules with DC input jack 46 or battery connection option (not shown) for active equalizers;
5) according to number of units—“one knob” 7, 11, “two knob” 8, 12, “three knob” 9, 13 and/or multi-knob 10, 14;
6) different shapes 7, 8, 9, 10, 11, 12, 13, 14.

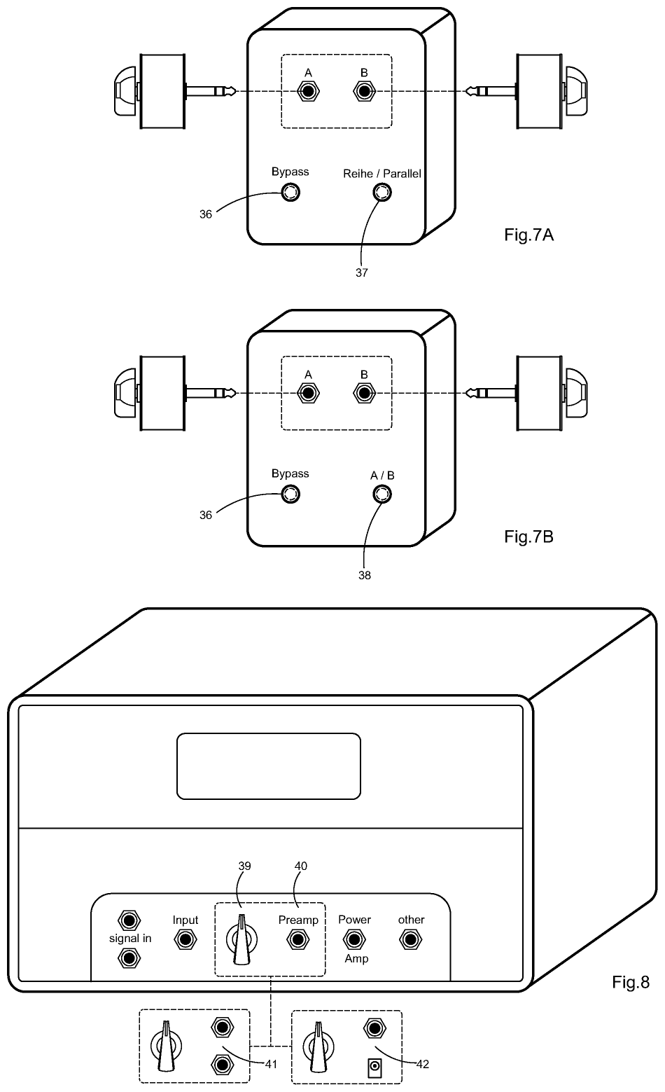

Although the invention has been described with reference to specific preferred embodiments thereof, many variations and modifications will be readily apparent. For example, a modular modding structure could be associated with a fixed tone control of a “one knob” audio amplifier FIG. 8. In this embodiment all the same elements are shown, operating in an identical manner as described in FIG. 2A, however a fixed tone control 39 is provided. Further illustrations show example variations of the “one knob” audio amplifier with mono connection pairs 41 as insert-send-return path or stereo connections with DC output sockets 42. Another possible example is a foot-switch modular modding structure FIG. 7A and FIG. 7B. In this embodiment all the same elements are shown operating in an identical manner as described in FIG. 3, but selector switches are provided for bypass 36, series/parallel 37 and AB test 38 switches. It is therefore the intention that the appended claims be interpreted as broadly as possible in view of the prior art to include all such variations and modifications.

What is claimed is:

1. A modular system for shaping the tone by circuit bending and modding of audio and sound equipment comprising:
a modding structure of a plurality of inserts, inputs and outputs connections for compatible modules, to reconfigure the electronic circuit without the physical changing of component values and without adding or removing electronic parts of the audio equipment by soldering;
a plurality of tone modules for shaping the sound by the intervention into the signal path;
a plurality of modules for shaping the tone by other sound design methods that are not part of the signal path.

2. The system of claim 1 wherein said modular system comprising:
at least one front to rear orifice in the chassis, which serves as a cable-tray to shield and enable the shortening of the patch cables, wherein the shape and size of the cross-section of the said orifice is optimized as required and metal and/or ferrite core shields are used for interference suppression.

3. The system of claim 1 wherein said modding structure and said tone modules are adapted for electric music instruments.

4. The system of claim 1 wherein said modding structure, said tone modules, said modules and said orifice-cable-tray are adapted for electronic music instruments.

5. The system of claim 1 wherein said modding structure, said tone modules, said modules and said orifice-cable-tray are adapted for audio amplifiers.

6. The system of claim 1 wherein said modding structure, said tone modules, said modules and said orifice-cable-tray are adapted for other audio and sound equipment.

7. An external apparatus to be used as a multiplier for said modular system of claim 1, comprising:
a chassis that defines a modding structure of a plurality of inserts, inputs and outputs connections for compatible modules also including a plurality of combined series/parallel circuits of freely selectable inputs and outputs for the direct swap of a plurality of modding modules;
at least one front to rear orifice in the chassis, which serves as a cable-tray to shield and enable the shortening of the patch cables, wherein the shape and size of the cross-section of the said orifice is optimized as required and metal and/or ferrite core shields are used for interference suppression.

8. The apparatus of claim 7 wherein said modding structure includes, DC input jacks or battery connection option for active equalizers.

9. The apparatus of claim 7 wherein said apparatus includes, AB test switches, series, parallel or combined connection of the tone modules switches, bypass functions of the modules switches.

10. A method of modular circuit bending and modding of electric and electronic music instruments, audio amplifiers and sound equipment, the method comprising:
configuring a plurality of inserts, inputs and outputs connections to the signal path and to other parts of the electronic circuit;
providing a plurality of tone modules for shaping the sound by the intervention into the signal path;
providing a plurality of modules for shaping the tone by other sound design methods that are not part of the signal path.

11. The method of claim 10, further comprising:
at least one front to rear orifice in the chassis of the audio amplifiers or sound equipment, to serves as a cable-tray to shield and enable the shortening of the patch cables, wherein the shape and size of the cross-section of the said orifice is optimized as required and metal and/or ferrite core shields are used for interference suppression.
